(19) United States
(12) Patent Application Publication
(10) Pub. No.: US 2019/0193374 A1
(43) Pub. Date: Jun. 27, 2019

(54) LAMINATE FOR FLEXIBLE IMAGE DISPLAY DEVICES, AND FLEXIBLE IMAGE DISPLAY DEVICE

(71) Applicant: NITTO DENKO CORPORATION, Ibaraki-shi, Osaka (JP)

(72) Inventors: Mizue Yamasaki, Ibaraki-shi (JP); Yusuke Toyama, Ibaraki-shi (JP); Yu Morimoto, Ibaraki-shi (JP)

(73) Assignee: NITTO DENKO CORPORATION, Ibaraki-shi, Osaka (JP)

(21) Appl. No.: 16/325,529

(22) PCT Filed: Aug. 2, 2017
(86) PCT No.: PCT/JP2017/028035

§ 371 Date: Feb. 14, 2019

(30) Foreign Application Priority Data
Aug. 15, 2016 (JP) 2016-159370

(51) Int. Cl. B32B 7/023; G02B 5/30; G02F 1/13363; G09F 9/30; H01L 27/32; H05B 33/02; H01L 51/50; G02F 1/1335

(52) U.S. Cl. CPC B32B 7/023; G02B 5/3083; G02F 1/13363; G09F 9/301; G02F 1/133528; H05B 33/02; H01L 51/5012; G02B 5/3025; H01L 27/32

(57) ABSTRACT

The disclosure provides a laminate for a flexible image display device by using an optical film including at least a polarizer and a plurality of specific pressure-sensitive adhesive layers, which exhibits excellent bending resistance and adhesiveness and does not peel or break even after repeated bending; and a flexible image display device in which the laminate for a flexible image display device is disposed. The laminate includes a plurality of pressure-sensitive adhesive layers and an optical film including at least a polarizer, wherein a thickness of the polarizer is 20 μm or less, and a storage elastic modulus G′ at 25° C. of the pressure-sensitive adhesive layer at an outermost surface on a convex side when the laminate is folded, among the plurality of pressure-sensitive adhesive layers, is substantially equal to or lower than the storage elastic modulus G′ at 25° C. of another pressure-sensitive adhesive layer.

### TECHNICAL FIELD

The present invention relates to a laminate for a flexible image display device, including an optical film including at least a polarizer and a plurality of specific pressure-sensitive adhesive layers, and a flexible image display device in which the laminate for a flexible image display device is disposed.

### BACKGROUND ART

As an organic EL display device integrated with a touch sensor, as shown in FIG. 1, an optical laminate 20 is provided on the viewing side of an organic EL display panel 10, and a touch panel 30 is provided on the viewing side of the optical laminate 20. The optical laminate 20 includes a polarizer 1 having protective films 2-1 and 2-2 bonded on both sides thereof and a retardation film 3, and a polarizer 1 is provided on the viewing side of the retardation film 3. Further, in the touch panel 30, transparent conductive films 4-1 and 4-2 having a structure in which base films 5-1 and 5-2 and transparent conductive layers 6-1 and 6-2 are laminated are disposed with an interposed spacer 7 (see, for example, Patent Document 1).

In addition, it is expected to realize a foldable organic EL display device which is more excellent in portability.

### PRIOR ART DOCUMENT

### Patent Document

Patent Document 1: JP-A-2014-157745

### SUMMARY OF THE INVENTION

### Problems to be Solved by the Invention

However, the conventional organic EL display device as disclosed in Patent Document 1 is not designed with bending in mind. When a plastic film is used for an organic EL display panel base material, bendability can be imparted to the organic EL display panel. In addition, even when the plastic film is used for the touch panel and incorporated in the organic EL display panel, bendability can be imparted to the organic EL display panel. However, a problem arises in that an optical film including a conventional polarizer or the like laminated on the organic EL display panel hinders the bendability of the organic EL display device.

Accordingly, the purpose of the present invention is to provide a laminate for a flexible image display device by using an optical film including at least a polarizer and a plurality of specific pressure-sensitive adhesive layers, which exhibits excellent bending resistance and adhesiveness and does not peel or break even after repeated bending; and a flexible image display device in which the laminate for a flexible image display device is disposed.

### Means for Solving the Problem

The laminate for a flexible image display device of the present invention is characterized by being a laminate for a flexible image display device including a plurality of pressure-sensitive adhesive layers and an optical film including at least a polarizer, wherein

a thickness of the polarizer is 20 μm or less, and

a storage elastic modulus G′ at 25° C. of the pressure-sensitive adhesive layer at the outermost surface on a convex side when the laminate is folded, among the plurality of pressure-sensitive adhesive layers, is substantially equal to or lower than the storage elastic modulus G′ at 25° C. of the other pressure-sensitive adhesive layer.

In the laminate for a flexible image display device of the present invention, it is preferable that the optical film is an optical laminate including the polarizer, a protective film of a transparent resin material on a first surface of the polarizer, and a retardation film on a second surface different from the first surface of the polarizer.

In the laminate for a flexible image display device of the present invention, it is preferable that a first pressure-sensitive adhesive layer among the plurality of pressure-sensitive adhesive layers is disposed on a side opposite to a surface in contact with the polarizer with respect to the protective film.

In the laminate for a flexible image display device of the present invention, it is preferable that a second pressure-sensitive adhesive layer among the plurality of pressure-sensitive adhesive layers is disposed on a side opposite to a surface in contact with the polarizer with respect to the retardation film.

In the laminate for a flexible image display device of the present invention, it is preferable that a transparent conductive layer forming a touch sensor is disposed on a side opposite to a surface in contact with the retardation film with respect to the second pressure-sensitive adhesive layer.

In the laminate for a flexible image display device of the present invention, it is preferable that a third pressure-sensitive adhesive layer is disposed on a side opposite to a surface in contact with the second pressure-sensitive adhesive layer with respect to the transparent conductive layer forming a touch sensor.

In the laminate for a flexible image display device of the present invention, it is preferable that a transparent conductive layer forming a touch sensor is disposed on a side opposite to a surface in contact with the protective film with respect to the first pressure-sensitive adhesive layer.

In the laminate for a flexible image display device of the present invention, it is preferable that a third pressure-sensitive adhesive layer among the plurality of pressure-sensitive adhesive layers is disposed on a side opposite to a surface in contact with the first pressure-sensitive adhesive layer with respect to the transparent conductive layer forming a touch sensor.

In the laminate for a flexible image display device of the present invention, it is preferable that the plurality of pressure-sensitive adhesive layers is formed from the same pressure-sensitive adhesive composition.

In the flexible image display device of the present invention including the laminate for a flexible image display device and an organic EL display panel, it is preferable that the laminate for a flexible image display device is disposed on a viewing side with respect to the organic EL display panel.

In the flexible image display device of the present invention, it is preferable that a window is disposed on a viewing side with respect to the laminate for a flexible image display device.

### Effect of the Invention

According to the present invention, by using an optical film including at least a polarizer and a plurality of specific pressure-sensitive adhesive layers, a laminate for a flexible image display device can be obtained without peeling and breaking even after repeated bending and with excellent properties in bending resistance and adhesiveness, and furthermore, a flexible image display device in which the laminate for a flexible image display device is disposed can be obtained, which is useful.

Embodiments of an optical film, a laminate for a flexible image display device, and a flexible image display device according to the present invention will be described in detail below with reference to the drawings and the like.

### BRIEF DESCRIPTION OF THE DRAWINGS

FIG. 1 is a cross-sectional view showing a conventional organic EL display device.

FIG. 2 is a cross-sectional view showing a flexible image display device according to an embodiment of the present invention.

FIG. 3 is a cross-sectional view showing a flexible image display device according to another embodiment of the present invention.

FIG. 4 is a cross-sectional view showing a flexible image display device according to another embodiment of the present invention.

FIG. 5 is a view showing a method for measuring folding endurance.

FIG. 6 is a cross-sectional view showing a sample for evaluation used in examples (Configuration A).

FIG. 7 is a cross-sectional view showing a sample for evaluation used in examples (Configuration B).

FIG. 8 is a view showing a method of producing a retardation used in examples.

FIG. 9 is a view showing a method of producing a retardation used in examples.

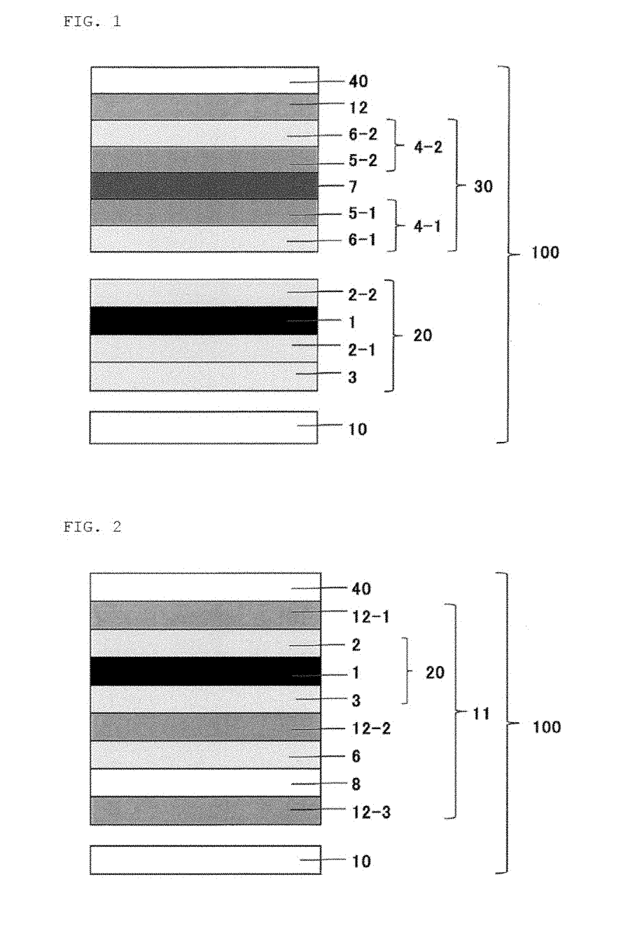

### MODE FOR CARRYING OUT THE INVENTION

### [Laminate for Flexible Image Display Device]

The laminate for a flexible image display device according to the present invention includes a plurality of pressure-sensitive adhesive layers and an optical film.

### [Optical Film]

The laminate for a flexible image display device of the present invention is characterized by including an optical film including at least a polarizer, wherein the optical film may refer to one including, in addition to the polarizer, a film such as a protective film and a retardation film formed of a transparent resin material.

Further, in the present invention, an optical laminate has a configuration such that the optical film includes, as the optical film, the polarizer, a protective film of a transparent resin material on the first surface of the polarizer, and a retardation film on a second surface different from the first surface of the polarizer. Note that the optical film does not include a plurality of pressure-sensitive adhesive layers such as a first pressure-sensitive adhesive layer described later.

The thickness of the optical film is preferably 92 μm or less, more preferably 60 μm or less, even more preferably 10 to 50 μm. Within the above range, a preferred embodiment is obtained without hindering the bending of the optical film.

As long as the properties of the present invention are not impaired, a protective film may be bonded to at least one side of the polarizer with an adhesive (layer) (not shown in the drawing). An adhesive can be used for the adhesion treatment of the polarizer and the protective film. Examples of the adhesive include isocyanate-based adhesives, polyvinyl alcohol-based adhesives, gelatin-based adhesives, vinyl-based latex, aqueous-based polyester and the like. The adhesive is usually used as an adhesive made of an aqueous solution, and usually contains 0.5 to 60% by weight of a solid content. Besides the above, as an adhesive between the polarizer and the protective film, an ultraviolet curable adhesive, an electron beam-curable adhesive and the like can be mentioned. The adhesive for electron beam-curable type polarizing film shows a suitable adhesion property to the various protective films mentioned above. The adhesive used in the present invention may contain a metal compound filler. In the present invention, those obtained by laminating a polarizer and a protective film with an adhesive (layer) may be sometimes referred to as a polarizing film (polarizing plate).

### <Polarizer>

In the polarizer used in the optical film of the present invention, a polyvinyl alcohol (PVA) based resin, which is stretched by a stretching step such as an in-air stretching (dry stretching) and a stretching in an aqueous boric acid and in which iodine is aligned, can be used.

Typically, as a method for producing the polarizer, there is a production method including a step of dyeing a single layer body of a PVA-based resin and a step of stretching such a single layer body as described in JP-A-2004-341515 (a monolayer stretching method). In addition, as described in JP-A-51-069644, JP-A-2000-338329, JP-A-2001-343521, WO 2010/100917, JP-A-2012-073563, and JP-A-2011-2816, there is exemplified a production method including a step of stretching a PVA-based resin layer and a stretching resin base material in the state of a laminate and a step of dyeing the laminate. According to this production method, even when the PVA-based resin layer is thin, such resin layer can be stretched without inconveniences such as breakage due to stretching because the resin layer is supported by the stretching resin base material.

As the production method including a step of stretching in the state of a laminate and a step of dyeing the laminate, an air stretching (dry stretching) method as described in JP-A-51-069644, JP-A-2000-338329, or JP-A-2001-343521 is exemplified. From the viewpoint of being able to stretching to a high drawing ratio and improve the polarization performance, a production method including a step of stretching in an aqueous boric acid solution as described in WO 2010/100917 A and JP-A-2012-073563 is preferable, and a production method (two-step stretching method) including a step of performing an auxiliary in-air stretching before stretching in an aqueous boric acid solution as described in JP-A-2012-073563 is particularly preferable. In addition, as described in JP-A-2011-2816, a method of stretching a PVA-based resin layer and a stretching resin base material in a laminate state, excessively dyeing the PVA-based resin layer, and then decoloring the dyed resin layer (excess dyeing decolorization method) is also preferable. The polarizer used in the optical film of the present invention is made of the polyvinyl alcohol-based resin in which iodine is aligned as described above and can be formed by laminating the polyvinyl alcohol-based resin stretched by a two-step stretching method including an auxiliary in-air stretching and a stretching in an aqueous boric acid solution. The polarizer is made of the polyvinyl alcohol-based resin in which iodine is aligned as described above and can be prepared by excessively dyeing a laminate of a stretched PVA-based resin layer and a resin base material for stretching, followed by decoloring.

The thickness of the polarizer is preferably 20 μm or less, preferably 12 μm or less, more preferably 9 μm or less, even more preferably 1 to 8 μm, particularly preferably 3 to 6 μm. Within the above range of the thickness of the polarizer, a preferred embodiment is obtained without hindering the bending.

### <Retardation Film>

The optical film that is used in the present invention can include a retardation film, and one obtained by stretching a polymer film or one obtained by aligning and fixing a liquid crystal material can be used. In this specification, the retardation film means a material having birefringence in the plane and/or thickness direction.

Examples of the retardation film may include an anti-reflection retardation film (see paragraphs [0221], [0222], and [0228] in JP-A-2012-133303), a viewing-angle compensating retardation film (see paragraphs [0225] and [0226] in JP-A-2012-133303), and a viewing-angle compensating obliquely-aligned retardation film (see paragraph [0227] in JP-A-2012-133303).

Any known retardation film substantially having any of the functions described above can be used irrespective of, for example, the retardation value, the arrangement angle, the three-dimensional birefringence index, whether or not a single layer or a multilayer, and other factors.

The thickness of the retardation film is preferably 20 μm or less, more preferably 10 μm or less, even more preferably 1 to 9 μm, particularly preferably 3 to 8 μm. Within the above range of the thickness of the retardation film, a preferred embodiment is obtained without hindering the bending.

<Protective film>

The optical film used in the present invention can include a protective film formed from a transparent resin material, and as the protective film (also referred to as a transparent protective film), a cycloolefin resin such as a norbornene resin, an olefin resin such as polyethylene and polypropylene, a polyester resin, a (meth)acrylic resin or the like can be used.

The thickness of the protective film is preferably 5 to 60 μm, more preferably 10 to 40 μm, even more preferably 10 to 30 μm, and a surface treatment layer, such as an anti-glare layer and an antireflection layer, may be provided as appropriate. Within the above range, a preferred embodiment is obtained without hindering the bending.

### [First Pressure-Sensitive Adhesive Layer]

Among the plurality of pressure-sensitive adhesive layers used in the laminate for a flexible image display device of the present invention, the first pressure-sensitive adhesive layer is preferably disposed on the side opposite to the surface in contact with the polarizer with respect to the protective film.

The pressure-sensitive adhesive layer forming the first pressure-sensitive adhesive layer used in the laminate for a flexible image display device according to the present invention is preferably an acrylic pressure-sensitive adhesive, a rubber-based pressure-sensitive adhesive, a vinyl alkyl ether-based pressure-sensitive adhesive, a silicone-based pressure-sensitive adhesive, a polyamide-based pressure-sensitive adhesive, an urethane-based pressure-sensitive adhesive, a fluorine-based pressure-sensitive adhesive, an epoxy-based pressure-sensitive adhesive, a polyether-based pressure-sensitive adhesive and the like. The pressure-sensitive adhesive forming the above-mentioned pressure-sensitive adhesive layer may be used singly or in combination of two or more thereof. However, from the viewpoints of transparency, processability, durability, adhesiveness, bending resistance, etc., it is preferable to use an acrylic pressure-sensitive adhesive alone.

### <(Meth)acrylic Polymer>

When an acrylic pressure-sensitive adhesive is used as the pressure-sensitive adhesive composition, a (meth)acrylic polymer containing, as a monomer unit, a (meth)acrylic monomer having a linear or branched alkyl group of 1 to 24 carbon atoms is preferably contained in the composition. By using the (meth)acrylic monomer having a linear or branched alkyl group of 1 to 24 carbon atoms, a pressure-sensitive adhesive layer excellent in bendability can be obtained. In the present invention, the term “(meth)acrylic polymer” refers to an acrylic polymer and/or a methacrylic polymer, and the term “(meth)acrylate” refers to an acrylate and/or a methacrylate.

Specific examples of the (meth)acrylic monomer having a linear or branched alkyl group of 1 to 24 carbon atoms forming the main skeleton of the (meth)acrylic polymer include methyl (meth)acrylate, ethyl (meth)acrylate, n-butyl (meth)acrylate, s-butyl (meth)acrylate, t-butyl (meth)acrylate, isobutyl (meth)acrylate, n-pentyl (meth)acrylate, isopentyl (meth)acrylate, n-hexyl (meth)acrylate, isohexyl (meth)acrylate, isoheptyl (meth)acrylate, 2-ethylhexyl (meth)acrylate, n-octyl (meth)acrylate, isooctyl (meth)acrylate, n-nonyl (meth)acrylate, isononyl (meth)acrylate, n-decyl (meth)acrylate, isodecyl (meth)acrylate, n-dodecyl (meth)acrylate, n-tridecyl (meth)acrylate, n-tetradecyl (meth)acrylate, etc. Among them, a monomer having a low glass transition temperature (Tg) generally becomes a viscoelastic body even in a high-speed region at the time of bending, so from the viewpoint of bendability, a (meth)acrylic monomer having a linear or branched alkyl group of 4 to 8 carbon atoms is preferred. As the (meth)acrylic monomer, one or two or more monomers can be used.

The linear or branched (meth)acrylic monomer having an alkyl group of 1 to 24 carbon atoms is a main component in all the monomers forming the (meth)acrylic polymer. Here, as the main component, the amount of (meth)acrylic monomer having a linear or branched alkyl group of 1 to 24 carbon atoms in all the monomers forming the (meth)acrylic polymer is 80 to 100% by weight, more preferably from 90 to 100% by weight, even more preferably from 92 to 99.9% by weight, particularly preferably from 94 to 99.9% by weight.

When an acrylic pressure-sensitive adhesive is used as the pressure-sensitive adhesive composition, it is preferable to contain a (meth)acrylic polymer including, as a monomer unit, a hydroxyl group-containing monomer having a reactive functional group. By using the hydroxyl group-containing monomer, a pressure-sensitive adhesive layer excellent in adhesiveness and bendability can be obtained. The hydroxyl group-containing monomer is a compound containing a hydroxyl group and a polymerizable unsaturated double bond such as a (meth)acryloyl group and a vinyl group in its structure.

Specific examples of the hydroxyl group-containing monomer include hydroxyalkyl (meth)acrylates such as 2-hydroxyethyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)-methyl acrylate. Among the hydroxyl group-containing monomers, 2-hydroxyethyl (meth)acrylate and 4-hydroxybutyl (meth)acrylate are preferable from the viewpoint of durability and adhesiveness. One or two or more kinds of the hydroxyl group-containing monomers may be used.

In addition, as the monomer unit forming the (meth)acrylic polymer, it is possible to contain a monomer having a reactive functional group, such as a carboxyl group-containing monomer, an amino group-containing monomer, and an amide group-containing monomer. It is preferable to use these monomers from the viewpoint of adhesiveness under moist heat environment.

When an acrylic pressure-sensitive adhesive is used as the pressure-sensitive adhesive composition, a (meth)acrylic polymer containing a carboxyl group-containing monomer having a reactive functional group can be contained as a monomer unit. By using the carboxyl group-containing monomer, it is possible to obtain a pressure-sensitive adhesive layer having an excellent adhesiveness under a moist heat environment. The carboxyl group-containing monomer is a compound containing a carboxyl group and a polymerizable unsaturated double bond such as a (meth)acryloyl group and a vinyl group in its structure.

Specific examples of the carboxyl group-containing monomer include (meth)acrylic acid, carboxyethyl (meth)acrylate, carboxypentyl (meth)acrylate, itaconic acid, maleic acid, fumaric acid, crotonic acid, and the like.

When an acrylic pressure-sensitive adhesive is used as the pressure-sensitive adhesive composition, a (meth)acrylic polymer containing, as a monomer unit, an amino group-containing monomer having a reactive functional group can be contained in the composition. By using the amino group-containing monomer, it is possible to obtain a pressure-sensitive adhesive layer having an excellent adhesiveness under a moist heat environment. The amino group-containing monomer is a compound containing an amino group and a polymerizable unsaturated double bond such as a (meth)acryloyl group and a vinyl group in its structure.

Specific examples of the amino group-containing monomer include N,N-dimethylaminoethyl (meth)acrylate, N,N-dimethylaminopropyl (meth)acrylate, and the like.

When an acrylic pressure-sensitive adhesive is used as the pressure-sensitive adhesive composition, a (meth)acrylic polymer containing, as a monomer unit, an amide group-containing monomer having a reactive functional group can be contained in the composition. By using the amide group-containing monomer, it is possible to obtain a pressure-sensitive adhesive layer having an excellent adhesiveness under a moist heat environment. The amide group-containing monomer is a compound containing an amide group and a polymerizable unsaturated double bond such as a (meth)acryloyl group and a vinyl group in its structure.

Specific examples of the amide group-containing monomer include acrylamide-based monomers such as (meth)acrylamide, N,N-dimethyl (meth)acrylamide, N,N-diethyl (meth)acrylamide, N-isopropylacrylamide, N-methyl (meth)acrylamide, N-butyl (meth)acrylamide, N-hexyl (meth)acrylamide, N-methylol (meth)acrylamide, N-methylol-N-propane (meth)acrylamide, aminomethyl (meth)acrylamide, aminoethyl (meth)acrylamide, mercaptomethyl (meth)acrylamide, and mercaptoethyl (meth)acrylamide; N-acryloyl heterocyclic monomers such as N-(meth)acryloyl morpholine, N-(meth)acryloyl piperidine, and N-(meth)acryloyl pyrrolidine; N-vinyl-containing lactam monomers such as N-vinylpyrrolidone and N-vinyl-ε-caprolactam; and the like.

As a monomer unit forming the (meth)acrylic polymer, the blending ratio (total amount) of the monomer having a reactive functional group is preferably 20% by weight or less, more preferably 10% by weight or less, even more preferably 0.01 to 8% by weight, particularly preferably 0.01 to 5% by weight, most preferably 0.05 to 3% by weight in the total monomers forming the (meth)acrylic polymer. When such blending ratio exceeds 20% by weight, the number of crosslinking points increases and the flexibility of the pressure-sensitive adhesive (layer) is lost, so that the stress relaxation property tends to be poor.

As the monomer unit forming the (meth)acrylic polymer, in addition to the monomer having a reactive functional group, other copolymerizable monomers can be introduced as long as the effect of the present invention is not impaired. The blending ratio is not particularly limited but is preferably 30% by weight or less with respect to all the monomers forming the (meth)acrylic polymer, and it is more preferable not to contain other copolymerizable monomers. When the blending ratio exceeds 30% by weight, in particular when a monomer other than the (meth)acrylic monomer is used, the reaction point with the film tends to be small and the adhesion tends to decrease.

In the present invention, when the (meth)acrylic polymer is used, such polymer usually has a weight average molecular weight (Mw) in the range of 1,000,000 to 2,500,000. In consideration of durability, particularly heat resistance and bendability, the weight average molecular weight is preferably from 1,200,000 to 2,200,000, more preferably from 1,400,000 to 2,000,000. When the weight average molecular weight is smaller than 1,000,000, at the time of crosslinking the polymer chains with each other in order to ensure durability, the number of crosslinking points is increased to lose the flexibility of the pressure-sensitive adhesive (layer), compared with those having a weight average molecular weight of 1,000,000 or more, and as a result, the dimensional change of the outer bend side (convex side) and the inner bend side (concave side) occurring between the films at the time of bending cannot be alleviated, and the film tends to break easily. In addition, when the weight average molecular weight exceeds 2,500,000, a large amount of a diluting solvent is required for adjusting the viscosity for coating, which undesirably leads to an increase in cost, and since the entanglement of the polymer chains of the resulting (meth)acrylic polymer becomes complicated, flexibility is inferior and breakage of the film is likely to occur at the time of bending. The weight average molecular weight (Mw) is a value calculated in terms of polystyrene as measured by GPC (gel permeation chromatography).

Such a (meth)acrylic polymer may be produced by a method selected appropriately from known production methods such as solution polymerization, bulk polymerization, emulsion polymerization and various radical polymerizations. The resultant (meth)acrylic polymer may be any one of random copolymers, block copolymers, graft copolymers, and the like.

In the solution polymerization, as a polymerization solvent, for example, ethyl acetate, toluene, or the like is used. In a specific example of the solution polymerization, a reaction is performed in the presence of a polymerization initiator in an inert gas, such as nitrogen, ordinarily under the reaction conditions of a temperature of about 50 to 70° C. and a period of about 5 to 30 hours.

A polymerization initiator, a chain transfer agent, an emulsifier and others that are used in the radical polymerizations are not particularly limited and may be used after appropriate selection. The weight average molecular weight of the (meth)acrylic polymer is controllable in accordance with the respective use amounts of the polymerization initiator and the chain transfer agent, and the reaction conditions. The amount of use thereof is appropriately adjusted according to the kind of these substances.

Examples of the polymerization initiator include, but are not limited to, azo initiators such as 2,2′-azobisisobutylonitrile, 2,2′-azobis(2-amidinopropane) dihydrochloride, 2,2′-azobis[2-(5-methyl-2-imidazolin-2-yl)propane] dihydrochloride, 2,2′-azobis(2-methylpropionamidine) disulfate, 2,2′-azobis(N,N′-dimethyleneisobutylamidine), and 2,2′-azobis[N-(2-carboxyethyl)-2-methylpropionamidine] hydrate (VA-057, manufactured by Wako Pure Chemical Industries, Ltd.); persulfates such as potassium persulfate and ammonium persulfate; peroxide initiators such as di(2-ethylhexyl) peroxydicarbonate, di(4-tert-butylcyclohexyl) peroxydicarbonate, di-sec-butyl peroxydicarbonate, tert-butyl peroxyneodecanoate, tert-hexyl peroxypivalate, tert-butyl peroxypivalate, dilauroyl peroxide, di-n-octanoyl peroxide, 1,1,3,3-tetramethylbutyl peroxy-2-ethylhexanoate, di(4-methylbenzoyl) peroxide, dibenzoyl peroxide, tert-butyl peroxyisobutylate, 1,1-di(tert-hexylperoxy) cyclohexane, tert-butyl hydroperoxide, and hydrogen peroxide; and redox system initiators of a combination of a peroxide and a reducing agent, such as a combination of a persulfate and sodium hydrogen sulfite and a combination of a peroxide and sodium ascorbate.

One of the above polymerization initiators may be used alone, or two or more thereof may be used in a mixture. The total content of the polymerization initiator is preferably from about 0.005 to 1 part by weight, more preferably from about 0.02 to about 0.5 parts by weight, per 100 parts by weight of all the monomers forming the (meth)acrylic polymer.

In the case of using a chain transfer agent, an emulsifier used for emulsion polymerization, or a reactive emulsifier, conventionally known ones can be appropriately used. In addition, these addition amounts can be appropriately determined within a range not to impair the effect of the present invention.

### <Crosslinking Agent>

The pressure-sensitive adhesive composition of the present invention may contain a crosslinking agent. An organic crosslinking agent or a polyfunctional metal chelate may be used as the crosslinking agent. Examples of the organic crosslinking agent include an isocyanate-based crosslinking agent, a peroxide-based crosslinking agent, an epoxy-based crosslinking agent, an imine-based crosslinking agent, and the like. The polyfunctional metal chelate may include those in which a polyvalent metal is covalently or coordinately bonded to an organic compound. Examples of the polyvalent metal atom include Al, Cr, Zr, Co, Cu, Fe, Ni, V, Zn, In, Ca, Mg, Mn, Y, Ce, Sr, Ba, Mo, La, Sn, and Ti. Examples of the atom in the organic compound that is covalently or coordinately bonded include an oxygen atom and the like. Examples of the organic compound include alkyl esters, alcohol compounds, carboxylic acid compounds, ether compounds, ketone compounds, and the like. Among them, an isocyanate-based crosslinking agent (particularly, a trifunctional isocyanate-based crosslinking agent) is preferable from the viewpoint of durability, and a peroxide-based crosslinking agent and an isocyanate-based crosslinking agent (in particular, a bifunctional isocyanate-based crosslinking agent) is preferable in terms of bendability. Both the peroxide-based crosslinking agent and the bifunctional isocyanate-based crosslinking agent form a flexible two-dimensional crosslinking, whereas the trifunctional isocyanate-based crosslinking agent forms a stronger three-dimensional crosslinking. When bending, two-dimensional crosslinking, which is a more flexible crosslinking, is advantageous. However, since two-dimensional crosslinking alone is poor in durability and peeling is likely to occur, hybrid crosslinking between two-dimensional crosslinking and three-dimensional crosslinking is favorable, so that a trifunctional isocyanate-based crosslinking agent and a peroxide-based crosslinking agent or a bifunctional isocyanate-based crosslinking agent are preferably used in combination.

The amount of the crosslinking agent to be used is preferably, for example, 0.01 to 10 parts by weight, more preferably 0.03 to 2 parts by weight, per 100 parts by weight of the (meth)acrylic polymer. Within the above range, an excellent bending resistance is obtained, which is a preferred embodiment.

### <Other Additives>

Further, the pressure-sensitive adhesive composition of the present invention may contain any other known additives, including, for example, various silane coupling agents, polyether compounds such as polyalkylene glycol (e.g. polypropylene glycol etc.), powder such as coloring agents and pigments, dyes, surfactants, plasticizers, tackifiers, surface lubricants, leveling agents, softeners, antioxidants, anti-ageing agents, light stabilizers, ultraviolet absorbers, polymerization inhibitors, antistatic agents (alkali metal salt or ionic liquid which are an ionic compound, etc.), inorganic or organic fillers, metal powder, particle- or foil-shaped materials, and the like, and such additives can be appropriately added depending on the intended use. In addition, a redox system including a reducing agent to be added may also be used in the controllable range.

### [Other Pressure-Sensitive Adhesive Layer]

Of the plurality of pressure-sensitive adhesive layers used in the laminate for a flexible image display device of the present invention, a second pressure-sensitive adhesive layer can be disposed on the side opposite to the surface in contact with the polarizer with respect to the retardation film.

Of the plurality of pressure-sensitive adhesive layers used in the laminate for a flexible image display device of the present invention, a third pressure-sensitive adhesive layer can be disposed on the side opposite to the surface in contact with the second pressure-sensitive adhesive layer with respect to the transparent conductive layer forming a touch sensor.

Of the plurality of pressure-sensitive adhesive layers used in the laminate for a flexible image display device of the present invention, a third pressure-sensitive adhesive layer can be disposed on the side opposite to the surface in contact with the first pressure-sensitive adhesive layer with respect to the transparent conductive layer forming a touch sensor.

In the case of using the second pressure-sensitive adhesive layer and further other pressure-sensitive adhesive layer (for example, third pressure-sensitive adhesive layer or the like) in addition to the first pressure-sensitive adhesive layer, these pressure-sensitive adhesive layers are not particularly limited and may have the same composition (same pressure-sensitive adhesive composition), may have the same characteristics, or may have different characteristics. However, among a plurality of pressure-sensitive adhesive layers, it is required that the storage elastic modulus G′ at 25° C. of the pressure-sensitive adhesive layer at the outermost surface on the convex side when the laminate is folded is substantially equal to or lower than the storage elastic modulus G′ at 25° C. of the other pressure-sensitive adhesive layer. From the viewpoints of workability, economic efficiency, and bendability, it is preferable that all the pressure-sensitive adhesive layers have substantially the same composition and the same characteristics.

### <Formation of Pressure-Sensitive Adhesive Layer>

The plurality of pressure-sensitive adhesive layers in the present invention are preferably formed from the pressure-sensitive adhesive composition. For example, the pressure-sensitive adhesive layer may be formed by a method including applying the pressure-sensitive adhesive composition to a release-treated separator or the like, removing the polymerization solvent and so on by drying to form a pressure-sensitive adhesive layer, or by a method including applying the pressure-sensitive adhesive composition to a polarizing film or the like, and removing the polymerization solvent and so on by drying to form a pressure-sensitive adhesive layer on the polarizing film. In applying the pressure-sensitive adhesive composition, one or more kinds of solvents other than the polymerization solvent may be newly added as needed.

A silicone release liner is preferably used as the release-treated separator. When the pressure-sensitive adhesive composition of the present invention is applied to such a liner and dried to form a pressure-sensitive adhesive layer, any appropriate drying method may be suitably adopted depending on the purpose. A method of drying under heating is preferably used. For example, in the case of preparing an acrylic adhesive containing a (meth)acrylic polymer, the heat drying temperature is preferably from 40° C. to 200° C., more preferably from 50° C. to 180° C., particularly preferably from 70° C. to 170° C. When the heating temperature is set in the above range, a pressure-sensitive adhesive layer having good adhesive properties can be obtained.

Any suitable drying time may be used as appropriate. For example, in the case of preparing an acrylic pressure-sensitive adhesive containing a (meth)acrylic polymer, the drying time is preferably from 5 seconds to 20 minutes, more preferably from 5 seconds to 10 minutes, particularly preferably from 10 seconds to 5 minutes.

As a coating method of the pressure-sensitive adhesive composition, various methods may be used. Specific examples of such methods include a roll coating method, a kiss roll coating method, a gravure coating method, a reverse coating method, a roll brush coating method, a spray coating method, a dip roll coating method, a bar coating method, a knife coating method, an air knife coating method, a curtain coating method, a lip coating method, and an extrusion coating method with a die coater or the like.

The thickness of the pressure-sensitive adhesive layer used in the laminate for a flexible image display device of the present invention is preferably 1 to 200 μm, more preferably 5 to 150 μm, even more preferably 10 to 100 μm. The pressure-sensitive adhesive layer may be a single layer or may have a laminated structure. A preferred embodiment is within the above range in terms of not inhibiting the bending and also in terms of adhesiveness (retention resistance). Further, in the case of having a plurality of pressure-sensitive adhesive layers, all the pressure-sensitive adhesive layers are preferably within the above-mentioned range.

Among the plurality of pressure-sensitive adhesive layers used in the laminate for a flexible image display device of the present invention, the pressure-sensitive adhesive layers is characterized in that the storage elastic modulus G′ at 25° C. of the pressure-sensitive adhesive layer at the outermost surface on the convex side when the laminate is bent is substantially equal to or lower than the storage elastic modulus G′ at 25° C. of the other pressure-sensitive adhesive layer. When a plurality of storage elastic moduli (G′) are substantially the same, stress generated at the time of bending (at the time of folding) is not biased to some layers, so that breakage of each film/each layer (for example, an optical film such as a polarizer) and peeling of the pressure-sensitive adhesive layer/adhesive layer are suppressed, which is preferable.

Further, for example, in the case where the optical laminate is used as the optical film, when the laminate for a flexible image display device is folded at the center with the retardation film side on the convex side (outer side) and the storage elastic modulus (G′) decreases toward the convex side, the pressure-sensitive adhesive layer on the retardation film side receives a force in the tensile direction and the tensile force decreases from the convex side (outside) to the concave side (inside). The pressure-sensitive adhesive layer which receives a force in the tensile direction relaxes the stress, that is, when G′ becomes smaller, the stress applied to the film such as the optical film becomes smaller, so that breakage or peeling between layers becomes less likely to occur. Since the stress applied from the convex side (outer side) toward the concave side (inner side) becomes small, the bending resistance is secured even if G′ becomes larger than the outermost layer side. As compared with the case where G′ becomes larger toward the convex side (outer side), breakage of each film/each layer and interlayer peeling are eliminated, which is a preferable embodiment.

The term “substantially same” means that the difference in storage elastic modulus (G′) between the pressure-sensitive adhesive layers is within the range of ±15%, preferably within the range of ±10%, with respect to the average value of the storage elastic modulus (G′) of the plurality of pressure-sensitive adhesive layers.

The storage elastic modulus (G′) of the pressure-sensitive adhesive layer used in the laminate for a flexible image display device of the present invention is preferably 1.0 MPa or less, more preferably 0.8 MPa or less, even more preferably 0.3 MPa or less at 25° C. When the storage elastic modulus of the pressure-sensitive adhesive layer is in such a range, it is difficult for the pressure-sensitive adhesive layer to become hard, and such a pressure-sensitive adhesive layer is excellent in stress relaxation property and superior in bending resistance, so that it is possible to realize a bendable or foldable flexible image display device.

In particular, when the laminate for a flexible image display device is folded at the center, the innermost storage elastic modulus (G′) at 25° C. of the concave side (inside) is preferably 0.05 to 0.2 MPa, more preferably 0.05 to 0.15 MPa. When the innermost storage elastic modulus exceeds 0.2 MPa, the stress applied at the time of bending cannot be relaxed, and the film such as the optical film tends to break. If the innermost storage elastic modulus is less than 0.05 MPa, such a modulus completely follows the dimensional change between films at the time of continuous bending. As a result, the durability of the bent portion is deteriorated due to fatigue deterioration of the pressure-sensitive adhesive layer, so that peeling and foaming are likely to occur.

Further, when the laminate for a flexible image display device is folded at the center, the outermost storage elastic modulus (G′) at 25° C. of the convex side (outer side) is preferably 0.01 to 0.15 MPa, more preferably 0.01 to 0.1 MPa. When the outermost storage elastic modulus exceeds 0.15 MPa, the shearing stress generated at the time of bending cannot be relaxed, and breakage of the film such as the optical film easily occurs. On the other hand, if the outermost storage elastic modulus is less than 0.01 MPa, such a modulus completely follows the dimensional change between films at the time of continuous bending. Thus, the durability of the bent portion is deteriorated due to fatigue deterioration of the pressure-sensitive adhesive layer and peeling and foaming are likely to occur.

When a plurality of pressure-sensitive adhesive layers is present, the storage elastic modulus (G′) at 25° C. of the pressure-sensitive adhesive layer positioned in the middle is preferably 0.01 to 0.2 MPa, more preferably 0.01 to 0.15 MPa. Since the pressure-sensitive adhesive layer is positioned in the middle of the laminate, the stress is hardly applied, so the range of the combined storage elastic moduli (G′) of the pressure-sensitive adhesive layers on the convex side (outer side) and the concave side (inner side) of the plurality of pressure-sensitive adhesive layers is an application range. Within the above range, breakage or the like of the convex side film does not occur at the time of bending, which is preferable.

The upper limit of the glass transition temperature (Tg) of the pressure-sensitive adhesive layer used in the laminate for a flexible image display device of the present invention is preferably 0° C. or less, more preferably −20° C. or less, even more preferably −25° C. or less. When the Tg of the pressure-sensitive adhesive layer is in such a range, the pressure-sensitive adhesive layer is difficult to harden even in a high-speed region at the time of bending, so that a flexible image display device excellent in stress relaxation property, which is bendable or foldable, can be realized.

The total light transmittance (according to JIS K7136) in the visible light wavelength region of the pressure-sensitive adhesive layer for flexible image display devices of the present invention is preferably 85% or more, more preferably 90% or more.

The haze (according to JIS K7136) of the pressure-sensitive adhesive layer for flexible image display devices of the present invention is preferably 3.0% or less, more preferably 2.0% or less.

Incidentally, the total light transmittance and the haze can be measured using, for example, a haze meter (trade name “HM-150”, manufactured by Murakami Color Research Laboratory).

### [Transparent Conductive Layer]

A member having a transparent conductive layer is not particularly limited and known materials can be used as such a member. The member includes those having a transparent conductive layer on a transparent base material such as a transparent film or the like and those having a transparent conductive layer and a liquid crystal cell.

The transparent base material may be of any type having transparency, and examples thereof include a base material (for example, a sheet-like, film-like, or plate-like base material) made of a resin film or the like. The thickness of the transparent base material is not particularly limited, but is preferably about 10 to 200 μm, more preferably about 15 to 150 μm.

The resin film may be made of any material, such as any of various plastic materials having transparency. Examples of such materials include polyester-based resins such as polyethylene terephthalate and polyethylene naphthalate, acetate-based resins, polyethersulfone-based resins, polycarbonate-based resins, polyamide-based resins, polyimide-based resins, polyolefin-based resins, (meth)acrylic resins, polyvinyl chloride-based resins, polyvinylidene chloride-based resins, polystyrene-based resins, polyvinyl alcohol-based resins, polyarylate-based resins, and polyphenylene sulfide-based resins. Among them, polyester-based resins, polyimide-based resins, and polyethersulfone-based resins are particularly preferred.

The surface of the transparent base material may be previously subjected to sputtering, corona discharge treatment, flame treatment, ultraviolet irradiation, electron beam irradiation, chemical treatment, etching treatment such as oxidation, or undercoating treatment so that the transparent base material can have improved adhesiveness to the transparent conductive layer formed thereon. Before the transparent conductive layer is formed, if necessary, the transparent base material may be subjected to solvent washing or ultrasonic washing for removal of dust and cleaning.

Examples of the material used to form the transparent conductive layer include, but not limited to, metal oxides of at least a metal selected from the group consisting of indium, tin, zinc, gallium, antimony, titanium, silicon, zirconium, magnesium, aluminum, gold, silver, copper, palladium, and tungsten. If necessary, the metal oxides may be doped with any metal from the group shown above. For example, tin oxide-doped indium oxide (ITO) and antimony-doped tin oxide are preferably used, and in particular, ITO is preferably used. ITO preferably includes 80 to 99% by weight of indium oxide and 1 to 20% by weight of tin oxide.

The ITO may be crystalline or amorphous. The crystalline ITO can be obtained by high-temperature sputtering or further heating an amorphous ITO.

The thickness of the transparent conductive layer of the present invention is preferably 0.005 to 10 μm, more preferably 0.01 to 3 μm, even more preferably 0.01 to 1 μm. When the thickness of the transparent conductive layer is less than 0.005 μm, the transparent conductive layer tends to be more variable in electric resistance. On the other hand, the transparent conductive layer with a thickness of more than 10 μm may be produced with lower productivity at higher cost and tend to have a lower level of optical properties.

The total light transmittance of the transparent conductive layer of the present invention is preferably 80% or more, more preferably 85% or more, even more preferably 90% or more.

The density of the transparent conductive layer of the present invention is preferably 1.0 to 10.5 g/cm³, more preferably 1.3 to 3.0 g/cm³.

The surface resistance value of the transparent conductive layer of the present invention is preferably 0.1 to 1000Ω/□, more preferably 0.5 to 500Ω/□, even more preferably 1 to 250Ω/□.

The method for forming the transparent conductive layer is not particularly limited, and conventionally known methods can be adopted. Specifically, for example, a vacuum deposition method, a sputtering method, and an ion plating method can be exemplified. In addition, an appropriate method can be adopted according to the required film thickness.

In addition, an undercoat layer, an oligomer prevention layer, and the like can be provided between the transparent conductive layer and the transparent base material, if necessary.

The transparent conductive layer forms a touch sensor and is required to be configured to be bendable.

In the laminate for a flexible image display device according to the present invention, the transparent conductive layer forming a touch sensor can be disposed on the side opposite to the surface in contact with the retardation film with respect to the second pressure-sensitive adhesive layer.

In the laminate for a flexible image display device according to the present invention, the transparent conductive layer forming a touch sensor can be disposed on the side opposite to the surface in contact with the protective film with respect to the first pressure-sensitive adhesive layer.

In the laminate for a flexible image display device according to the present invention, the transparent conductive layer forming a touch sensor can be disposed between the protective film and a window film (OCA).

The transparent conductive layer can be suitably applied to a liquid crystal display device incorporating a touch sensor such as an in-cell type or an on-cell type as a case of being used for a flexible image display device, and in particular, a touch sensor may be built in (may be incorporated in) an organic EL display panel.

### [Conductive Layer (Antistatic Layer)]

Further, the laminate for a flexible image display device of the present invention may have a layer having conductivity (a conductive layer, an antistatic layer). Since the laminate for a flexible image display device has a bending function and has a very thin thickness structure, such a laminate is highly responsive to feeble static electricity generated in a manufacturing process or the like and is easily damaged, but by providing a conductive layer in the laminate, the load due to static electricity in the manufacturing process and the like is largely reduced, which is a preferable embodiment.

In addition, it is one of the major features for the flexible image display device including the laminate to have a bending function, but in the case of continuous bending, static electricity may be generated due to shrinkage between the films (base materials) at the bent portion. Therefore, when conductivity is imparted to the laminated body, generated static electricity can be promptly removed, and damage caused by static electricity of the image display device can be reduced, which is a preferable embodiment.

Further, the conductive layer may be an undercoat layer having a conductive function, a pressure-sensitive adhesive containing a conductive component, or a surface treatment layer containing a conductive component. For example, a method of forming a conductive layer between a polarizer and a pressure-sensitive adhesive layer by using an antistatic composition containing a binder and a conductive polymer such as polythiophene can be employed. Further, a pressure-sensitive adhesive containing an ionic compound which is an antistatic agent can also be used. The conductive layer preferably has one or more layers and may contain two or more layers.

### [Flexible Image Display Device]

The flexible image display device of the present invention includes the laminate for a flexible image display device and an organic EL display panel, and the laminate for a flexible image display device is disposed on the viewing side with respect to the organic EL display panel and configured to be foldable. A window may be optionally disposed on the viewing side with respect to the laminate for a flexible image display device.

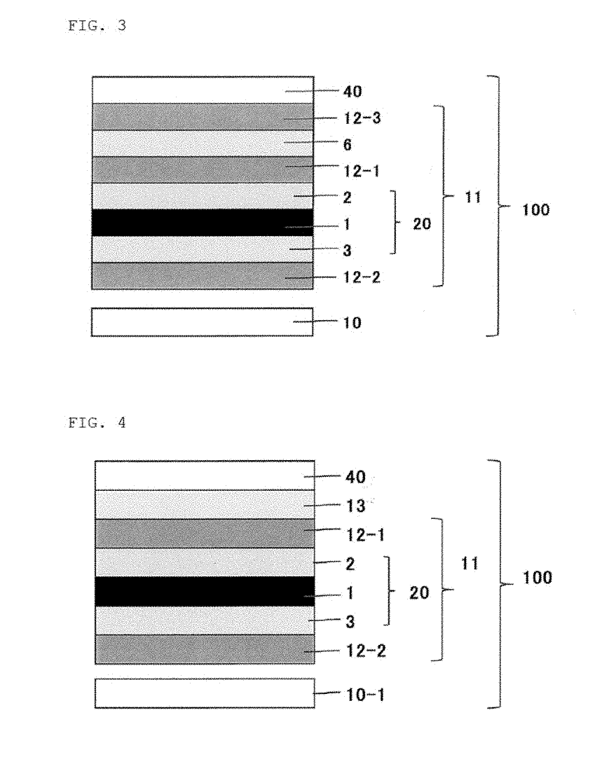

FIG. 2 is a cross-sectional view showing one embodiment of a flexible image display device according to the present invention. A flexible image display device 100 includes a laminate 11 for a flexible image display device and an organic EL display panel 10 configured to be foldable. The laminate 11 for a flexible image display device is disposed on the viewing side with respect to the organic EL display panel 10, and the flexible image display device 100 is configured to be foldable. Further, although optional, a transparent window 40 can be disposed on the viewing side with an interposed first pressure-sensitive adhesive layer 12-1 with respect to the laminate 11 for a flexible image display device.

The laminate 11 for a flexible image display device includes the optical laminate 20 and a pressure-sensitive adhesive layer forming a second pressure-sensitive adhesive layer 12-2 and a third pressure-sensitive adhesive layer 12-3.

The optical laminate 20 includes a polarizer 1, a protective film 2 made of a transparent resin material, and a retardation film 3. The protective film 2 made of a transparent resin material is bonded to a first surface on the viewing side of the polarizer 1. The retardation film 3 is bonded to a second surface different from the first surface of the polarizer 1. For example, the polarizer 1 and the retardation film 3 generate circularly polarized light in order to prevent light incident inside from the viewing side of the polarizer 1 from being internally reflected and emitted to the viewing side, or to compensate a viewing angle.

In the present embodiment, a protective film is provided on one side only, whereas a protective film is conventionally provided on both sides of a polarizer, and the thickness of the optical laminate 20 can be reduced by using a polarizer having a very thin thickness (for example, 20 μm or less) as compared with the polarizer used in the conventional organic EL display device. In addition, since the polarizer 1 is much thinner than the polarizer used in the conventional organic EL display device, stress due to expansion and contraction occurring under temperature or humidity conditions becomes extremely smaller. Therefore, the possibility that the stress caused by the shrinkage of the polarizer causes deformation such as warping in the adjacent organic EL display panel 10 is greatly reduced, and the deterioration of the display quality due to deformation and breakage of the panel sealing material can be greatly suppressed. In addition, by using a thin polarizer, bending is not hindered, which is a preferable embodiment.

In the case of bending the optical laminate 20 with the protective film 2 side as the inside, the thickness (for example, 92 μm or less) of the optical laminate 20 is thinned and the first pressure-sensitive adhesive layer 12-1 having the storage elastic modulus as described above is disposed on the side opposite to the retardation film 3 with respect to the protective film 2 to make it possible to reduce the stress applied to the optical laminate 20, whereby the optical laminate 20 can be folded. Therefore, an appropriate range of the storage elastic modulus may be set according to the environmental temperature in which the flexible image display device is used. For example, in the case where the assumed use environmental temperature is from −20° C. to +85° C., it is possible to use a first pressure-sensitive adhesive layer in such a manner that the storage elastic modulus at 25° C. falls within an appropriate numerical range.

Optionally, a foldable transparent conductive layer 6 forming a touch sensor may further be disposed on the side opposite to the protective film 2 with respect to the retardation film 3. The transparent conductive layer 6 is configured to be directly bonded to the retardation film 3 by a manufacturing method as disclosed in, for example, JP-A-2014-219667, whereby the thickness of the optical laminate 20 is reduced and the stress applied to the optical laminate 20 when the optical laminate 20 is folded can be further reduced.

Optionally, a pressure-sensitive adhesive layer forming a third pressure-sensitive adhesive layer 12-3 can be further disposed on the side opposite to the retardation film 3 with respect to the transparent conductive layer 6. In the present embodiment, the second pressure-sensitive adhesive layer 12-2 is directly bonded to the transparent conductive layer 6. By providing the second pressure-sensitive adhesive layer 12-2, it is possible to further reduce the stress applied to the optical laminate 20 when folded.

The flexible image display device shown in FIG. 3 is substantially the same as that shown in FIG. 2. In the flexible image display device of FIG. 2, a foldable transparent conductive layer 6 forming a touch sensor is disposed on the side opposite to the protective film 2 with respect to the retardation film 3, whereas in the flexible image display device of FIG. 3, a foldable transparent conductive layer 6 forming a touch sensor is disposed on the side opposite to the protective film 2 with respect to the first pressure-sensitive adhesive layer 12-1. This is a different point. Further, there is a different point in that in the flexible image display device of FIG. 2, the third pressure-sensitive adhesive layer 12-3 is disposed on the side opposite to the retardation film 3 with respect to the transparent conductive layer 2, whereas in the flexible image display device of FIG. 3, the second pressure-sensitive adhesive layer 12-2 is disposed on the side opposite to the protective film 2 with respect to the retardation film 3.

In addition, although optional, the third pressure-sensitive adhesive layer 12-3 can be disposed when the window 40 is disposed on the viewing side with respect to the laminate 11 for a flexible image display device.

The flexible image display device of the present invention can be suitably used as a flexible liquid crystal display device, an organic EL (electroluminescence) display device, and an electronic paper. Further, such a flexible image display device can be used irrespective of a touch panel or the like such as a resistive film type or a capacitive type.

In addition, the flexible image display device of the present invention may also be used as an in-cell type flexible image display device in which the transparent conductive layer 6 forming a touch sensor is incorporated in an organic EL display panel 10-1, as shown in FIG. 4.

### EXAMPLES

Several examples relating to the present invention will be described below, but the present invention is not intended to be limited to such specific examples. In addition, the numerical values in tables are blending amounts (addition amounts) and showed solid contents or solid fractions (weight basis). The contents of the formulation and the evaluation results are shown in Tables 1 to 4.

### Example 1

### [Polarizer]

An amorphous polyethylene terephthalate (hereinafter referred to as “PET”) (IPA-copolymerized PET) film (thickness: 100 μm) with 7 mol % of isophthalic acid unit was used as a thermoplastic resin base material, and a surface of the film was subjected to a corona treatment (58 W/m²/min).

Further, a PVA (polymerization degree: 4200, saponification degree: 99.2%) added with 1 wt % of acetoacetyl-modified PVA (trade name: Gohsefimer Z200 (average polymerization degree: 1200, saponification degree: 98.5 mol %, acetoacetyl-modification degree: 5 mol %), manufactured by Nippon Synthetic Chemical Industry Co., Ltd.) was used to preliminarily prepare a coating solution consisting of an aqueous PVA solution containing 5.5 wt % of PVA-based resin. Then, the coating solution was applied onto a base material to allow a film thickness after drying to become 12 μm and subjected to hot-air drying under an atmosphere at 60° C. for 10 minutes to prepare a laminate in which a layer of the PVA-based resin is provided on the base material.

Then, this laminate was first subjected to free-end stretching in air (auxiliary in-air stretching) at 130° C. at a stretching ratio of 1.8 times to form a stretched laminate. Then, the stretched laminate was immersed in a boric acid insolubilizing aqueous solution having a temperature of 30° C. for 30 seconds to perform a step of insolubilizing a PVA layer in which PVA molecules are aligned and which is contained in the stretched laminate. The boric acid insolubilizing aqueous solution in this step was prepared to allow a boric acid to be contained in an amount of 3 weight parts with respect to 100 weight parts of water. The stretched laminate was subjected to dyeing to form a dyed laminate. The dyed laminate was prepared by immersing the stretched laminate in a dyeing solution containing iodine and potassium iodide and having a temperature of 30° C. for an arbitrary time, in such a manner that a single layer transmittance of a PVA layer making up a polarizer to be finally obtained falls with the range of 40 to 44%, thereby causing the PVA layer included in the stretched laminate to be dyed with iodine. In this step, the dyeing solution was prepared using water as a solvent to allow an iodine concentration and a potassium iodide concentration to fall with the range of 0.1 to 0.4% by weight, and the range of 0.7 to 2.8% by weight, respectively. A concentration ratio of iodine to potassium iodide was 1:7. Then a step of immersing the dyed laminate in a boric acid crosslinking aqueous solution at 30° C. for 60 seconds so as to subject PVA molecules in the PVA layer having iodine adsorbed therein to a cross-linking treatment was performed. The boric acid crosslinking aqueous solution in this step was set to contain boric acid in an amount of 3 weight parts with respect to 100 parts by weight of water and contain potassium iodide in an amount of 3 parts by weight with respect to 100 parts by weight of water.

Further, an obtained dyed laminate was stretched in an aqueous boric acid solution (stretching in an aqueous boric acid solution) at a stretching temperature of 70° C., at a stretching ratio of 3.05 times in the same direction as that during the previous in-air stretching to obtain an optical film laminate stretched at a final (total) stretching ratio of 5.50 times. The optical film laminate was taken out of the aqueous boric acid solution, and a boric acid attaching on a surface of the PVA layer was washed with an aqueous solution containing 4 parts by weight of potassium iodide with respect to 100 pars by weight of water. The washed optical film laminate was dried through a drying step using hot air at 60° C. The polarizer included the obtained optical film laminate had a thickness of 5 μm.

### [Protective Film]

A protective film obtained by extruding a methacrylic resin pellet having a glutarimide ring unit to forma film shape and then stretching the film was used. This protective film had a thickness of 20 μm and was an acrylic film having a moisture permeability of 160 g/m².

Next, the polarizer and the protective film were bonded using an adhesive shown below to obtain a polarizer.

As the adhesive (active energy ray-curable adhesive), each component was mixed according to the formulation table shown in Table 1 and stirred at 50° C. for 1 hour to prepare an adhesive (active energy ray-curable adhesive A). Numerical values in the table indicate weight % when the total amount of the composition is taken as 100% by weight. Each component used is as follows.

HEAA: Hydroxyethylacrylamide

M-220: ARONIX M-220, tripropylene glycol diacrylate) manufactured by Toagosei Co., Ltd.

ACMO: Acryloyl morpholine

AAEM: 2-Acetoacetoxyethyl methacrylate, manufactured by The Nippon Synthetic Chemical Industry Co., Ltd.

UP-1190: ARUFON UP-1190, manufactured by Toagosei Co., Ltd.

IRG 907: IRGACURE 907, 2-methyl-1-(4-methylthiophenyl)-2-morpholinopropan-1-one, manufactured by BASF

DETX-S: KAYACURE DETX-S, diethylthioxanthone, manufactured by Nippon Kayaku Co., Ltd.

TABLE 1

| (wt %) | Adhesive composition |
|---|---|
| HEAA | 11.4 |
| M-220 | 57.1 |
| ACMO | 11.4 |
| AAEM | 4.6 |
| UP-1190 | 11.4 |
| IRG 907 | 2.8 |
| DETX-S | 1.3 |

In examples and comparative examples using the adhesive, after the protective film and the polarizer were laminated with the interposed adhesive, the adhesive was cured by irradiation with ultraviolet light to form an adhesive layer. For irradiation with ultraviolet rays, a gallium-encapsulated metal halide lamp (trade name “Light HAMMER 10” manufactured by Fusion UV Systems, Inc., bulb: Vbulb, peak illuminance: 1600 mW/cm², integrated irradiation amount: 1000/mJ/cm² (wavelength 380 to 440 nm)) was used.

### [Retardation Film]

The retardation film (a quarter wavelength retardation plate) of this example was a retardation film composed of two layers of a retardation layer for a quarter wavelength plate and a retardation layer for a half wavelength plate, in which a liquid crystal material is aligned and fixed. Specifically, such a retardation film was manufactured as follows.

### (Liquid Crystal Material)

A polymerizable liquid crystal material (trade name: PALIOCOLOR LC242, manufactured by BASF) showing a nematic liquid crystal phase was used as a material for forming a retardation layer for a half wavelength plate and a retardation layer for a quarter wavelength plate. A photopolymerization initiator (trade name IRGACURE 907, manufactured by BASF) for the polymerizable liquid crystal material was dissolved in toluene. Further, for the purpose of improving the coating property, a MEGAFACE series manufactured by DIC Corporation was added in an amount of about 0.1 to 0.5% according to the liquid crystal thickness to prepare a liquid crystal coating solution. The liquid crystal coating solution was applied on an alignment base material with a bar coater, dried by heating at 90° C. for 2 minutes, and subjected to alignment fixation by ultraviolet curing under a nitrogen atmosphere. As the base material, for example, one capable of transferring the liquid crystal coating layer later, such as PET, was used. Further, for the purpose of improving coatability, a fluorine-based polymer which is a MEGAFACE series made by DIC Corporation was added in an amount of about 0.1% to 0.5% depending on the thickness of the liquid crystal layer, and MIBK (methyl isobutyl ketone), cyclohexanone, or a mixed solvent of MIBK and cyclohexanone was used to dissolve the polymer to a solid content concentration of 25%, thereby to prepare a coating solution. This coating solution was applied on a base material with a wire bar, dried at 65° C. for 3 minutes, and subjected to alignment fixation by ultraviolet curing under a nitrogen atmosphere to perform the preparation. As the base material, for example, one capable of transferring the liquid crystal coating layer later, such as PET, was used.

### (Manufacturing Process)

The manufacturing process of the present example will be described with reference to FIG. 8. The numbers in FIG. 8 are different from the numbers in other drawings. In this manufacturing process 20, a base material 14 was provided by a roll, and this base material 14 was supplied from a supply reel 21. In the manufacturing process 20, a coating solution of an ultraviolet curable resin 10 was applied to the base material 14 by a die 22. In the manufacturing process 20, a roll plate 30 was a cylindrical shaping mold in which a concavo-convex shape relating to an alignment film for a quarter wavelength plate of a quarter wavelength retardation plate was formed on the peripheral side surface. In the manufacturing process 20, the base material 14 coated with the ultraviolet curable resin is pressed against the circumferential side surface of the roll plate 30 by a pressure roller 24, and the ultraviolet curable resin was irradiated with ultraviolet light by an ultraviolet irradiation device 25 composed of a high-pressure mercury lamp and then cured. As a result, in the manufacturing process 20, the concavo-convex shape formed on the peripheral side surface of the roll plate 30 was transferred to the base material 14 so as to be at 75° with respect to the MD direction. Thereafter, the base material 14 integrally with the cured ultraviolet curable resin 10 was peeled from the roll plate 30 by a peeling roller 26, and the liquid crystal material was applied by a die 29. After that, the liquid crystal material was cured by irradiation with ultraviolet rays by an ultraviolet irradiation device 27, whereby a configuration relating to the retardation layer for a quarter wavelength plate was formed.

Subsequently, in this step 20, the base material 14 is conveyed to a die 32 by a conveying roller 31, and the coating solution of an ultraviolet curable resin 12 is applied onto the retardation layer for a quarter wavelength plate of the base material 14 by the die 32. In this manufacturing process 20, a roll plate 40 was a cylindrical shaping mold in which a concavo-convex shape relating to the alignment film for a half wavelength plate of the quarter wavelength retardation plate was formed on the circumferential side surface. In the manufacturing process 20, the base material 14 coated with the ultraviolet curing resin was pressed against the peripheral side surface of the roll plate 40 by a pressure roller 34, and the ultraviolet curable resin was irradiated with ultraviolet rays by an ultraviolet irradiation device 35 composed of a high-pressure mercury lamp, and then cured. As a result, in the manufacturing process 20, the concavo-convex shape formed on the circumferential side surface of the roll plate 40 was transferred onto the base material 14 so as to be at 15° with respect to the MD direction. Thereafter, the base material 14 integrally with the cured ultraviolet curable resin 12 was peeled from the roll plate 40 by a peeling roller 36, and the liquid crystal material was applied thereon by a die 39. After that, the liquid crystal material was cured by irradiation with ultraviolet rays by an ultraviolet irradiation device 37, whereby a configuration relating to the retardation layer for a half wavelength plate was obtained. Thus, a retardation film having a thickness of 7 μm and composed of two layers of a retardation layer for a quarter wavelength plate and a retardation layer for a half wavelength plate was obtained.

### [Optical Film (Optical Laminate)]

The retardation film obtained as described above and the polarizing film obtained as described above were continuously laminated by the roll-to-roll method using the adhesive to prepare a laminated film (optical laminate) so that an axis angle became 45° between the slow axis and the absorption axis.

Subsequently, the obtained laminated film (optical laminate) was cut into a size of 15 cm×5 cm.

### [Second Pressure-Sensitive Adhesive Layer]

### <Preparation of (Meth)acrylic Polymer A1>

A monomer mixture containing 99 parts by weight of butyl acrylate (BA) and 1 part by weight of 4-hydroxybutyl acrylate (HBA) was charged into a four-necked flask equipped with a stirring blade, a thermometer, a nitrogen gas inlet tube and a condenser.

Further, 0.1 parts by weight of 2,2′-azobisisobutyronitrile as a polymerization initiator together with ethyl acetate were added to 100 parts (solid content) by weight of the monomer mixture, and nitrogen gas was introduced thereto with gentle stirring. After purging with nitrogen, polymerization reaction was carried out for 7 hours while maintaining the liquid temperature in the flask at around 55° C. Thereafter, ethyl acetate was added to the obtained reaction solution to prepare a solution of a (meth)acrylic polymer A1 having a weight average molecular weight of 1,600,000 which was adjusted to have a solid content concentration of 30% by addition of ethyl acetate.

### <Preparation of Acrylic Pressure-Sensitive Adhesive Composition>

An acrylic pressure-sensitive adhesive composition was prepared by blending 0.1 parts by weight of an isocyanate-based crosslinking agent (trade name: TAKENATE D 110N, trimethylolpropane xylylene diisocyanate, manufactured by Mitsui Chemicals, Inc.), 0.3 parts by weight of a peroxide-based crosslinking agent, benzoyl peroxide (trade name: NYPER BMT, manufactured by NOF Corporation), and 0.08 parts by weight of a silane coupling agent (trade name: KBM 403, manufactured by Shin-Etsu Chemical Co., Ltd.) with 100 parts by weight of the solid content of the obtained (meth)acrylic polymer A1 solution.

<Preparation of Pressure-Sensitive Adhesive Layer Attached Optical Laminate>

The acrylic pressure-sensitive adhesive composition was uniformly applied to the surface of a polyethylene terephthalate film (PET film, transparent base material, separator) having a thickness of 38 μm treated with a silicone-based releasing agent using a fountain coater, and dried at 155° C. in an air circulation type thermostatic oven for 2 minutes to forma pressure-sensitive adhesive layer 1 (second pressure-sensitive adhesive layer) having a thickness of 25 μm on the surface of the base material.

Next, a separator having a pressure-sensitive adhesive layer 1 (second pressure-sensitive adhesive layer) formed thereon was transferred to the protective film side (corona-treated side) of the obtained optical laminate to prepare a pressure-sensitive adhesive layer attached an optical laminate.

### [First Pressure-Sensitive Adhesive Layer]

In the same manner as in the formation of the second pressure-sensitive adhesive layer, a pressure-sensitive adhesive layer 4 (first pressure-sensitive adhesive layer) having a thickness of 50 μm was formed on the basis of the contents of the formulations in Tables 2 and 3, and a separator having the pressure-sensitive adhesive layer 4 formed thereon was transferred to the surface (corona-treated) of a PET film having a thickness of 75 μm (transparent base material, manufactured by Mitsubishi Plastics, Inc., trade name: DIAFOIL) to form a pressure-sensitive adhesive layer attached a PET film.

### [Third Pressure-Sensitive Adhesive Layer]

In the same manner as in the formation of the second pressure-sensitive adhesive layer, a pressure-sensitive adhesive layer 2 (third pressure-sensitive adhesive layer) having a thickness of 50 μm was formed on the basis of the contents of the formulations in Tables 2 and 3, and a separator having the pressure-sensitive adhesive layer 2 formed thereon was transferred to the surface (corona-treated) of a polyimide film having a thickness of 77 μm (PI film, KAPTON 300 V, base material, manufactured by Du Pont-Toray Co., Ltd.) to form a pressure-sensitive adhesive layer attached a PI film.

### <Laminate for Flexible Image Display Device>

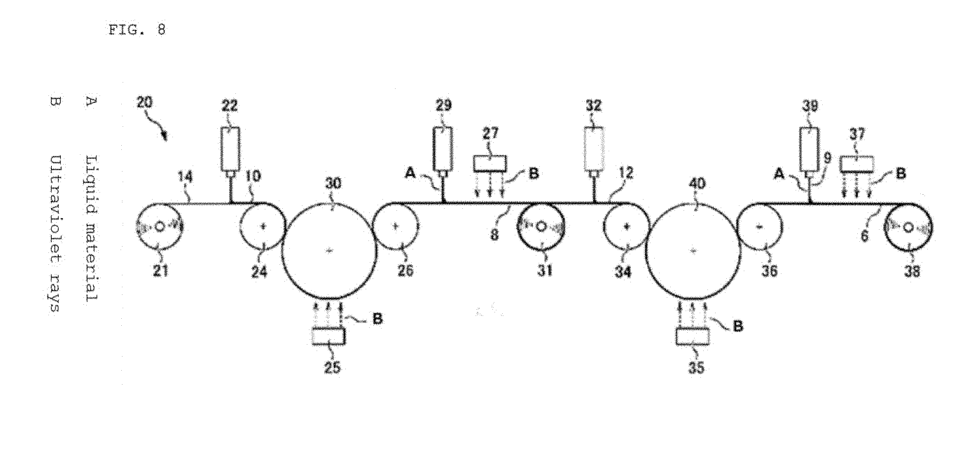

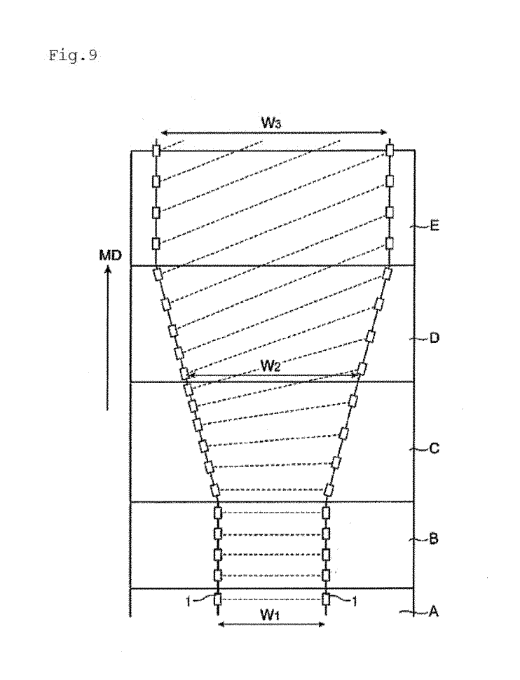

As shown in FIG. 6, with respect to the first to third pressure-sensitive adhesive layers (together with each transparent base material) obtained as described above, the second pressure-sensitive adhesive layer 12-2 was bonded to a (meth)acrylic resin film which will be the protective film 2, the third pressure-sensitive adhesive layer 12-3 was bonded to the retardation film 3, and further, the first pressure-sensitive adhesive layer 12-1 was bonded to a transparent base material 8-2 (PET film) to which the second pressure-sensitive adhesive layer 12-2 was attached, thereby to produce the laminate 11 for a flexible image display device corresponding to the configuration A used in Example 1. The laminate 11 for a flexible image display device corresponding to the configuration B was shown in FIG. 7.

### <Preparation of (Meth)acrylic Polymer A3>

(Meth)acrylic polymer A3 was prepared in the same manner as in the preparation of the (meth)acrylic polymer A1, except that the polymerization reaction was carried out with a mixing ratio (weight ratio) of ethyl acetate and toluene of 95/5 in the polymerization reaction for 7 hours while maintaining the liquid temperature in the flask at around 55° C.

### <Preparation of (Meth)Acrylic Oligomer (Oligomer)>

A four-necked flask equipped with a stirring blade, a thermometer, a nitrogen gas inlet tube, and a condenser was loaded with 99 parts by weight of butyl acrylate (BA), 2 parts by weight of acrylic acid (AA), 3 parts by weight of 2-mercaptoethanol, 0.1 parts by weight of 2,2′-azobisisobutyronitrile as a polymerization initiator, and 140 parts by weight of toluene, and nitrogen gas was introduced into the flask with gentle stirring to thoroughly purge the inside thereof with nitrogen. While keeping the liquid temperature in the flask at about 70° C., the polymerization reaction was carried out for 8 hours to prepare an acrylic oligomer solution. The acrylic oligomer had a weight average molecular weight of 4,500. A predetermined amount of the obtained oligomer was added at the time of mixing the crosslinking agent or the like to prepare an acrylic pressure-sensitive adhesive composition. By using such an oligomer, an effect of improving durability and suppressing foaming of the pressure-sensitive adhesive layer can be expected.

### Example 8

A silicone pressure-sensitive adhesive composition was obtained by mixing 100 parts by weight of an addition reaction type silicone pressure-sensitive adhesive (trade name “X-40-3306”, manufactured by Shin-Etsu Chemical Co., Ltd.) and 0.2 parts by weight of a platinum catalyst (trade name “CAT-PL-50T”, manufactured by Shin-Etsu Chemical Co., Ltd.). This was applied to a transparent base material such as a PET film and a PI film, in such a manner that the thickness after drying was 50 μm for each of the first pressure-sensitive adhesive layer and the third pressure-sensitive adhesive layer, and 25 μm for the second pressure-sensitive adhesive layer, and dried at 100° C. for 3 minutes to obtain a silicone-based pressure-sensitive adhesive layer (pressure-sensitive adhesive layer 6) (common to the first to third pressure-sensitive adhesive layers).

### Comparative Example 1

### [Polarizer]

A polyvinyl alcohol film having a thickness of 50 μm was immersed in five baths of the following [1] to [5], successively, while applying tension in the longitudinal direction of the film through a plurality of sets of rolls having different peripheral speeds so that the final draw ratio was 6.0 times the original film length. This film was dried in an oven at 50° C. for 4 minutes to obtain a polarizer having a thickness of 22 μm.

[1] Swelling bath: Pure water of 30° C.
[2] Dyeing bath: The iodine concentration was set within the range of 0.02 to 0.2% by weight and the potassium iodide concentration was set within the range of 0.14 to 1.4% by weight with respect to 100 parts by weight of water. The ratio of the concentration of iodine to potassium iodide is 1:7. The film was immersed in an aqueous solution containing these at 30° C. for an arbitrary time so that the polarizer had a single body transmittance of 40 to 44%.
[3] First crosslinking bath: An aqueous solution at 40° C. containing 3% by weight of potassium iodide and 3% by weight of boric acid.
[4] Second crosslinking bath: An aqueous solution at 60° C. containing 5% by weight of potassium iodide and 4% by weight of boric acid.
[5] Washing bath: An aqueous solution at 25° C. containing 3% by weight of potassium iodide.

Next, the polarizer and the protective film used in Example 1 were laminated using the adhesive used in Example 1 to prepare a polarizer.

### [Optical Film (Optical Laminate)]

The retardation film used in Example 1 and the polarizing film obtained as described above were laminated using the adhesive used in Example 1, and a laminated film was prepared so that the axis angle between the slow axis and the absorption axis was 45°.

### Examples 2 to 8 and Comparative Examples 1 to 3

In the preparation of the polymer ((meth)acrylic polymer) to be used, the pressure-sensitive adhesive composition, and the pressure-sensitive adhesive layer, a laminate for a flexible image display device was prepared in the same manner as in Example 1 except that each composition other than specified was changed as shown in Tables 2 to 4. Only in Example 5, a configuration B (see FIG. 7) not including the second pressure-sensitive adhesive layer was adopted.

Abbreviations in Tables 2 and 3 are as follows.

BA: n-Butyl acrylate

2EHA: 2-Ethylhexyl acrylate

AA: Acrylic acid

HBA: 4-Hydroxybutyl acrylate

HEA: 2-Hydroxyethyl acrylate

D 110N: Trimethylolpropane/xylylene diisocyanate adduct (trade name: TAKENATE D 110N, manufactured by Mitsui Chemicals, Inc.)

C/L: Trimethylolpropane/tolylene diisocyanate (trade name: CORONATE L, manufactured by Nippon Polyurethane Industry Co., Ltd.)

Peroxide: Benzoyl peroxide (peroxide-based crosslinking agent, trade name: NYPER BMT, manufactured by NOF Corporation)

### [Evaluation]

### <Measurement of Weight Average Molecular Weight (Mw) of (Meth)acrylic Polymer>

The weight average molecular weight (Mw) of the obtained (meth)acrylic polymer was measured by GPC (gel permeation chromatography).

Analyzer: HLC-8120 GPC, manufactured by Tosoh Corporation

Column: G7000H_{XL}+GMH_{XL}+GMH_{XL}, manufactured by Tosoh Corporation

Column size: each 7.8 mmφ×30 cm, 90 cm in total

Column temperature: 40° C.

Flow rate: 0.8 ml/min

Injection volume: 100 μl

Eluent: Tetrahydrofuran

Detector: Differential refractometer (RI)

Standard sample: Polystyrene

### (Measurement of Thickness)

The thickness of each of the polarizer, the protective film, the pressure-sensitive adhesive layer, and the transparent base material was calculated together with measurement using a dial gauge (manufactured by Mitutoyo Corporation).

### (Measurement of Storage Elastic Modulus G′ of Pressure-Sensitive Adhesive Layer)

A separator was peeled from the pressure-sensitive adhesive sheet of each of examples and comparative examples, and a plurality of pressure-sensitive adhesive sheets were laminated to prepare a test sample having a thickness of about 1.5 mm. The test sample was punched into a disk shape having a diameter of 7.9 mm, sandwiched between parallel plates, and dynamic viscoelasticity measurement was performed using “Advanced Rheometric Expansion System (ARES)” manufactured by Rheometric Scientific, Inc. under the following conditions. From the measurement results, the storage elastic modulus G′ at 25° C. of the pressure-sensitive adhesive layer was read.

### (Measurement Conditions)

Deformation mode: twisting

Measurement temperature: −40° C. to 150° C.

Rate of temperature increase: 5° C./min

### (Folding Endurance Test)

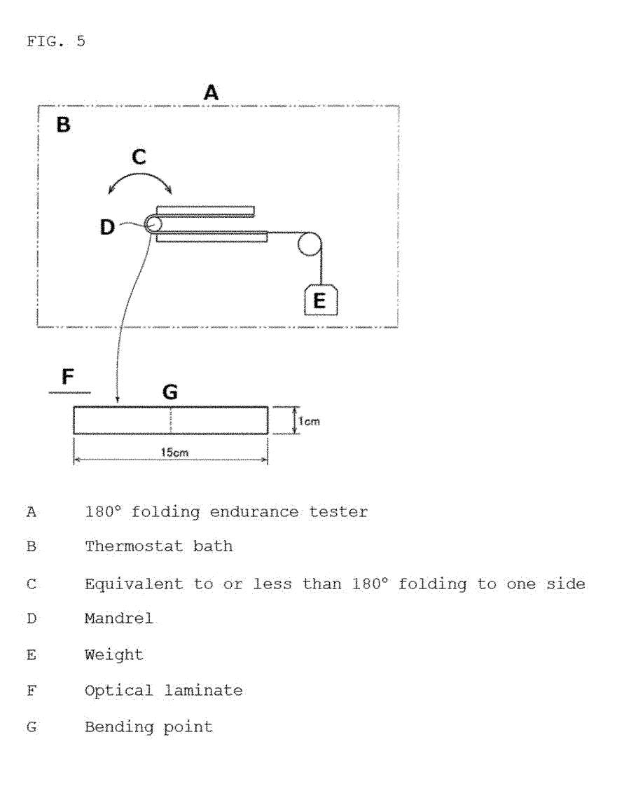

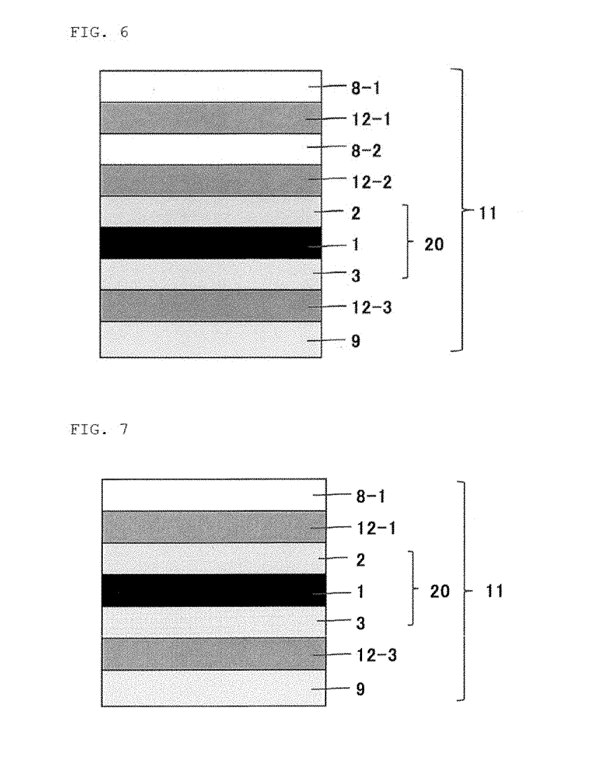

FIG. 5 is a schematic view of a 180° folding endurance tester (manufactured by Imoto Machinery Co., Ltd.). This tester has a mechanism in which a chuck on one side repeats 180° bending across a mandrel and is capable of changing a bending radius on the basis of the diameter of the mandrel. In the tester, the test is stopped when the film breaks. The laminate (5 cm×15 cm) for flexible image display devices, obtained in each of examples and comparative examples, was set in the tester and the folding endurance test was performed under the conditions of a temperature of 25° C., a bending angle of 180°, a bending radius of 3 mm, a bending rate of 1 second/time, and a weight of 100 g. Folding endurance was evaluated on the basis of the number of times of folding at which breakage of the laminate for a flexible image display device occurred. When the number of folding reached 200,000 times, the test was terminated.

As a measurement (evaluation) method, in the case of folding the first pressure-sensitive adhesive layer side of the laminate for a flexible image display device to the inner side (concave side) (only in Example 1), two types of folding (bending) directions were evaluated when folding the first pressure-sensitive adhesive layer to the outer side (convex side).

### <Presence or Absence of Breakage>

∘: No breakage
Δ: Occurrence of slight breakage at the end of the bent portion (practically no problem)
x: Occurrence of breakage on the entire surface of the bent portion (problematic in practical use)

### <Presence or Absence of Appearance Defects (Peeling)>

∘: Bending and peeling etc. are not observed.
Δ: Slight bending and peeling etc. are observed at the bent portion (practically no problem).
x: Bending and peeling etc. are observed on the entire surface of the bent portion (problematic in practical use).

TABLE 2

| (Meth)acrylic | | | | | | Molecular weight | |
|---|---|---|---|---|---|---|---|
| polymer to | Composition | | | | | of (meth)acrylic | |
| be used | BA | 2EHA | AA | HBA | HEA | polymer | |
| A1 | 99 | | | 1 | | 1.6 | million |
| A2 | | 99.9 | | | 0.1 | 1.75 | million |
| A3 | 94.9 | | 5 | | 0.1 | 2 | million |

TABLE 3

| Formulation/ | | | | | | | |
|---|---|---|---|---|---|---|---|
| characteristics | (Meth)acrylic | | | | | | |
| of pressure- | polymer to be used | | | | | | G′ |
| sensitive | | Blending | Crosslinking agent | | | | (25° C.) |
| adhesive layer | Kind | amount | D110N | C/L | Peroxide | Additive | [MPa] |
| 1 | A1 | 100 | 0.1 | | 0.3 | | 0.08 |
| 2 | A1 | 100 | 0.03 | | 0.3 | Oligomer: 30 | 0.05 |
| 3 | A2 | 100 | | 0.15 | | | 0.06 |
| 4 | A3 | 100 | | 0.6 | | | 0.11 |
| 5 | A3 | 100 | | 10 | | | 0.18 |

TABLE 4

| | | | | | Configuration (combination of | | | | | | | | |
|---|---|---|---|---|---|---|---|---|---|---|---|---|---|
| | | | | | pressure-sensitive adhesive layers) | | | | | | | | |
| | | | | | First | | Second | | Third | | | | |
| | | | | | pressure- | | pressure- | | pressure- | | | | |
| | | Optical laminate | | | sensitive | | sensitive | | sensitive | | | | |
| | | Polar- | Retarda- | Protec- | adhesuve | | adhesive | | adhesive | | | Folding | |
| | | izer | tion film | tive film | layer | | layer | | layer | | | endurance test | |
| | | Thick- | Thick- | Thick- | | G′ | | G′ | | G′ | | 25° C. | |
| Evaluation | Config- | ness | ness | ness | | (25° C.) | | (25° C.) | | (25° C.) | | Break- | Appear- |
| results | uration | [μm] | [μm] | [μm] | Kind | [MPa] | Kind | [MPa] | Kind | [MPa] | Bending direction | age | ance |
| Example 1 | A | 5 | 7 | 20 | 4 | 0.11 | 1 | 0.08 | 1 | 0.08 | First pressure-sensitive | ∘ | ∘ |
| | | | | | | | | | | | adhesive layer on inner | | |
| | | | | | | | | | | | side | | |
| Example 2 | A | 5 | 7 | 20 | 3 | 0.06 | 1 | 0.08 | 1 | 0.08 | First pressure-sensitive | ∘ | ∘ |
| | | | | | | | | | | | adhesive layer on outer | | |
| | | | | | | | | | | | side | | |
| Example 3 | A | 5 | 7 | 20 | 1 | 0.08 | 4 | 0.11 | 1 | 0.08 | First pressure-sensitive | ∘ | ∘ |
| | | | | | | | | | | | adhesive layer on outer | | |
| | | | | | | | | | | | side | | |
| Example 4 | A | 5 | 7 | 20 | 1 | 0.08 | 1 | 0.08 | 1 | 0.08 | First pressure-sensitive | ∘ | ∘ |
| | | | | | | | | | | | adhesive layer on outer | | |
| | | | | | | | | | | | side | | |
| Example 5 | B | 5 | 7 | 20 | 1 | 0.08 | — | — | 4 | 0.11 | First pressure-sensitive | ∘ | ∘ |
| | | | | | | | | | | | adhesive layer on outer | | |
| | | | | | | | | | | | side | | |
| Example 6 | A | 5 | 7 | 20 | 1 | 0.08 | 1 | 0.08 | 5 | 0.18 | First pressure-sensitive | Δ | ∘ |
| | | | | | | | | | | | adhesive layer on outer | | |
| | | | | | | | | | | | side | | |
| Example 7 | A | 5 | 7 | 20 | 4 | 0.11 | 5 | 0.18 | 5 | 0.18 | First pressure-sensitive | Δ | Δ |
| | | | | | | | | | | | adhesive layer on outer | | |
| | | | | | | | | | | | side | | |
| Example 8 | A | 5 | 7 | 20 | 6 | 0.10 | 6 | 0.10 | 6 | 0.10 | First pressure-sensitive | ∘ | Δ |
| | | | | | | | | | | | adhesive layer on outer | | |
| | | | | | | | | | | | side | | |
| Comparative | A | 22 | 7 | 20 | 1 | 0.08 | 1 | 0.08 | 1 | 0.08 | First pressure-sensitive | x | x |
| example 1 | | | | | | | | | | | adhesive layer on outer | | |
| | | | | | | | | | | | side | | |
| Comparative | A | 5 | 7 | 20 | 4 | 0.11 | 1 | 0.08 | 2 | 0.05 | First pressure-sensitive | x | x |
| example 2 | | | | | | | | | | | adhesive layer on outer | | |
| | | | | | | | | | | | side | | |
| Comparative | A | 5 | 7 | 20 | 5 | 0.18 | 1 | 0.08 | 1 | 0.08 | First pressure-sensitive | x | Δ |
| example 3 | | | | | | | | | | | adhesive layer on outer | | |
| | | | | | | | | | | | side | | |

From the evaluation results in Table 4, it was confirmed by folding endurance tests that there is no problem in practical use in folding or peeling in all the examples. That is, in the laminate for a flexible image display device of each example, by using a thinner polarizer to be used and by using a plurality of specific pressure-sensitive adhesive layers, it was confirmed that a laminate for a flexible image display device, which is excellent in bending resistance and adhesiveness, could be obtained without peeling or breakage even after repeated bending.

On the other hand, in Comparative Example 1, since the thickness of the polarizer exceeded the desired range, the bending resistance was confirmed to be inferior. In Comparative Examples 2 and 3, the storage elastic modulus G′ at 25° C. of the pressure-sensitive adhesive layer on the outermost surface of the convex side when folded is larger than the storage elastic modulus G′ at 25° C. of the other pressure-sensitive adhesive layer. As a result, it was confirmed that folding, peeling etc. occurred in the laminate and the bending resistance and adhesiveness were poor.

Although the present invention has been described with reference to the drawings concerning specific embodiments, the present invention can be modified in a number of ways other than the illustrated and described configurations. Accordingly, the present invention is not limited to the illustrated and described configurations, and the scope of the present invention is to be determined only by the appended claims and their equivalents.

### DESCRIPTION OF REFERENCE SIGNS

1 Polarizer
2 Protective film
2-1 Protective film
2-2 Protective film
3 Retardation layer
4-1 Transparent conductive film
4-2 Transparent conductive film
5-1 Base material film
5-2 Base material film
6 Transparent conductive layer
6-1 Transparent conductive layer
6-2 Transparent conductive layer
7 Spacer
8 Transparent base material
8-1 Transparent base material (PET film)
8-2 Transparent base material (PET film)
9 Base material (PI film)
10 Organic EL display panel
10-1 Organic EL display panel (provided with touch sensor)
11 Laminate for flexible image display device (laminate for organic EL display device)
12 Pressure-sensitive adhesive layer
12-1 First pressure-sensitive adhesive layer
12-2 Second pressure-sensitive adhesive layer
12-3 Third pressure-sensitive adhesive layer
13 Decorative printing film
20 Optical laminate
30 Touch panel
40 Window
100 Flexible image display device (organic EL display device)

1. A laminate for a flexible image display device, comprising a plurality of pressure-sensitive adhesive layers and an optical film including at least a polarizer, wherein
a thickness of the polarizer is 20 μm or less, and
a storage elastic modulus G′ at 25° C. of the pressure-sensitive adhesive layer at an outermost surface on a convex side when the laminate is folded, among the plurality of pressure-sensitive adhesive layers, is substantially equal to or lower than the storage elastic modulus G′ at 25° C. of another pressure-sensitive adhesive layer.

2. The laminate for a flexible image display device according to claim 1, wherein the optical film is an optical laminate including the polarizer, a protective film of a transparent resin material on a first surface of the polarizer, a retardation film on a second surface different from the first surface of the polarizer.

3. The laminate for a flexible image display device according to claim 2, wherein a first pressure-sensitive adhesive layer among the plurality of pressure-sensitive adhesive layers is disposed on a side opposite to a surface in contact with the polarizer with respect to the protective film.

4. The laminate for a flexible image display device according to claim 2, wherein a second pressure-sensitive adhesive layer among the plurality of pressure-sensitive adhesive layers is disposed on a side opposite to a surface in contact with the polarizer with respect to the retardation film.

5. The laminate for a flexible image display device according to claim 4, wherein a transparent conductive layer forming a touch sensor is disposed on a side opposite to a surface in contact with the retardation film with respect to the second pressure-sensitive adhesive layer.

6. The laminate for a flexible image display device according to claim 5, wherein a third pressure-sensitive adhesive layer is disposed on a side opposite to a surface in contact with the second pressure-sensitive adhesive layer with respect to the transparent conductive layer forming a touch sensor.

7. The laminate for a flexible image display device according to claim 3, wherein a transparent conductive layer forming a touch sensor is disposed on a side opposite to a surface in contact with the protective film with respect to the first pressure-sensitive adhesive layer.

8. The laminate for a flexible image display device according to claim 7, wherein a third pressure-sensitive adhesive layer among the plurality of pressure-sensitive adhesive layers is disposed on a side opposite to a surface in contact with the first pressure-sensitive adhesive layer with respect to the transparent conductive layer forming a touch sensor.

9. The laminate for a flexible image display device according to claim 1, wherein the plurality of pressure-sensitive adhesive layers is formed from the same pressure-sensitive adhesive composition.

10. A flexible image display device comprising the laminate for a flexible image display device according to claim 1 and an organic EL display panel, wherein the laminate for a flexible image display device is disposed on a viewing side with respect to the organic EL display panel.

11. The flexible image display device according to claim 10, wherein a window is disposed on a viewing side with respect to the laminate for a flexible image display device.
